(19) United States
(12) Patent Application Publication
(10) Pub. No.: US 2024/0213027 A1
(43) Pub. Date: Jun. 27, 2024

(54) PLASMA-ENHANCED METHOD OF DEPOSITING MOLYBDENUM

(71) Applicant: ASM IP Holding B.V., Almere (NL)

(72) Inventors: YoungChol Byun, Tempe, AZ (US); Holger Saare, Scottsdale, AZ (US); Sukanya Datta, Phoenix, AZ (US)

(21) Appl. No.: 18/545,183

(22) Filed: Dec. 19, 2023

Related U.S. Application Data
(60) Provisional application No. 63/434,606, filed on Dec. 22, 2022.

(51) Int. Cl. H01L 21/285; H01J 37/32

(52) U.S. Cl. CPC H01L 21/28568; H01J 37/32522; C23C 16/06; H01J 2237/2001; H01J 2237/332

(57) ABSTRACT

Methods and systems of depositing molybdenum are disclosed. Exemplary methods include using a plasma-assisted deposition process to non-selectively and/or conformally form plasma-deposited molybdenum on a first material and on a second material.

### CROSS-REFERENCE TO RELATED APPLICATIONS

This application is a nonprovisional of, and claims priority to and the benefit of, U.S. Provisional Patent Application No. 63/434,606, filed Dec. 22, 2022 and entitled “PLASMA-ENHANCED METHOD OF DEPOSITING MOLYBDENUM,” which is hereby incorporated by reference herein.

### FIELD OF INVENTION

The present disclosure generally relates to methods of depositing material on a substrate surface. More particularly, the disclosure relates to plasma-enhanced deposition methods.

### BACKGROUND OF THE DISCLOSURE

Conductive layers are often formed during the manufacture of electronic devices. For example, device structures that are formed during the manufacture of electronic devices often include conductive layers of tungsten or copper, which can form, for example, conductive plugs or lines within vias or trenches formed within dielectric material. Tungsten and copper can diffuse through most dielectric material. Accordingly, manufacturing techniques that employ deposition of tungsten or copper often include use of barrier layers, such as titanium nitride, to mitigate diffusion of tungsten, copper or the like, thereby improving device reliability and device yield. However, the barrier layer commonly exhibits a high electrical resistivity and therefore results in an increase in the overall electrical resistivity of the semiconductor device structure. Furthermore, formation of a barrier layer adds to a complexity of forming structures including conductive layers and generally requires additional equipment. For example, the barrier layer is often formed in one reaction chamber and the conductive layer (e.g., copper or tungsten) is formed in another reaction chamber.

Recently, molybdenum has gained interest as a metal for forming conductive layers during the manufacture of electronic devices. Devices formed using molybdenum can exhibit lower resistivity and better device performance, compared to devices formed using tungsten. Further, an additional barrier layer may not be required. However, techniques to deposit molybdenum in a desired manner—e.g., relatively evenly over a variety of materials, at a relatively low temperature, and/or with the molybdenum having desired properties, may not be well developed. For example, a lack of nucleation sites on dielectric material may make it difficult to evenly deposit molybdenum on the dielectric material and a metal. This selectivity can be amplified during low temperature deposition. Therefore, improved methods of depositing molybdenum are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of exemplary embodiments of the disclosure below. This summary is not intended to necessarily identify key features or essential features of the claimed subject matter, nor is it intended to be used to limit the scope of the claimed subject matter.

Various embodiments of the present disclosure relate to methods of depositing molybdenum. Such methods can be used to form structures suitable for use in forming electronic devices. While the ways in which various embodiments of the present disclosure address drawbacks of prior methods are discussed in more detail below, in general, embodiments of the disclosure provide improved methods that include plasma-assisted deposition at relatively low temperatures to obtain desired selectivity (or non-selectivity) of molybdenum on a variety of surfaces. As set forth in more detail below, in some cases, examples of the disclosure can be used to at least partially fill a gap or recess on a substrate surface. Use of plasma-assisted deposition allows non-selective deposition of molybdenum and deposition of molybdenum with desired properties. The plasma-assisted deposition can be used to form a molybdenum liner, to fill a gap, both, or the like.

In accordance with embodiments of the disclosure, a method of depositing molybdenum includes providing a substrate within a reaction chamber and using a plasma-assisted deposition process to form plasma-deposited molybdenum on a first material and on a second material. The substrate includes a surface comprising the first material and the second material, which can be the same or different than the first material. In accordance with examples of the disclosure, the method is non-selective, such that a selectivity of the plasma-deposited molybdenum on the first material relative to the second material is between about 40 percent and about 60 percent. In accordance with further examples, the plasma-deposited molybdenum is conformally deposited on the first material and the second material. In accordance with further examples, a temperature within the reaction chamber during the step of using the plasma-assisted deposition process is relatively low—e.g., less than 350° C. In some cases, the first material can be or include a conductive material. In some cases, the second material may be or include a dielectric material. In some cases, the substrate includes a feature having a bottom surface comprising the first material and a side surface comprising the second material, such as a gap or trench having such materials at the bottom, and a sidewall. In accordance with further examples, the method may be or include a cyclical deposition and etch process, wherein a cycle of the cyclical deposition and etch process includes the plasma-assisted deposition process and a step of etching a portion of the plasma-deposited molybdenum. Such a process can be used to fill a gap in a void-free and/or seam-free manner, and may be particularly well suited for filling high aspect ratio gaps (e.g., gaps having an aspect ratio greater than 10). In some cases, the method can further include depositing additional molybdenum under different plasma conditions and/or using a thermal (non-plasma-assisted) process. In accordance with these cases, the method can include passivating a portion of a surface of the plasma-deposited molybdenum prior to the step of forming or depositing the subsequently- (e.g., thermally-) deposited molybdenum. In accordance with further examples, the method can include a surface cleaning step prior to the step of using a plasma-assisted deposition process to form plasma-deposited molybdenum. As set forth in more detail below, the plasma-assisted deposition process can be a cyclical plasma-assisted deposition process (e.g., wherein a reducing agent is continually flowed to the reaction chamber during one or more cycles of the cyclical plasma-assisted deposition process), a pulsed-plasma chemical vapor deposition process, a plasma-enhanced chemical vapor deposition process, or the like.

In accordance with further examples of the disclosure, a method includes selectively (e.g., thermally or using plasma conditions suited for selective deposition) depositing molybdenum to form initially/thermally-deposited molybdenum on the first material relative to the second material, wherein a selectivity of the molybdenum deposited on the first material and the molybdenum deposited on the second material is greater than 60 percent and using a plasma-assisted deposition process, depositing molybdenum to form plasma-deposited molybdenum on the initially/thermally-deposited molybdenum. Such a method can include the cleaning and/or passivating steps as described herein, except the passivating can be on the (e.g., cleaned) substrate. The plasma-deposited molybdenum can be formed as described above and elsewhere herein.

These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a substrate including a gap for use in accordance with embodiments of the disclosure.

FIGS. 3 and 4 illustrate structures in accordance with further embodiments of the disclosure.

FIG. 5 illustrates another method in accordance with exemplary embodiments of the disclosure.

FIGS. 6 and 7 illustrate structures in accordance with further embodiments of the disclosure.

FIG. 8 illustrates a system in accordance with yet additional embodiments of the disclosure.

FIG. 9 illustrates a timing sequence suitable for use with a method in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Moreover, recitation of multiple embodiments having stated features is not intended to exclude other embodiments having additional features or other embodiments incorporating different combinations of the stated features. Unless otherwise noted, the exemplary embodiments or components thereof may be combined in various combinations or may be applied separate from each other. The illustrations presented herein are not meant to be actual views of any particular material, structure, or device, but are merely representations that are used to describe embodiments of the disclosure.

As set forth in more detail below, embodiments of the disclosure relate to a method of depositing molybdenum. Exemplary methods can be used to fill a gap on a surface of a substrate. Exemplary embodiments described herein may be particularly suitable for use in front end of line (FEOL), middle of line (MOL), and/or back end of line (BEOL) processes used to form electronic devices. For example, the methods can be used to deposit molybdenum that is suitable for applications, such as, for example, low electrical resistivity gap-fill layers for 3D-NAND and DRAM word-line features or as an interconnect material in CMOS logic applications. Exemplary methods provide molybdenum (e.g., in a gap) that exhibits relatively low effective electrical resistivity and/or other desired properties noted herein.

In this disclosure, gas can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term precursor can refer to a compound that participates in the chemical reaction that produces another compound, and particularly to a compound that constitutes a film matrix or a main skeleton of a film; the term reactant can be used to refer to a gas that reacts with the precursor or derivative thereof to form a desired material (e.g., molybdenum metal). In some cases, the term reactant can be used interchangeably with the term precursor. The term inert gas can refer to a gas that does not take part in a chemical reaction and/or does not become a part of a film matrix to an appreciable extent. Exemplary inert gases include helium, argon, and any combination thereof.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material. As described in more detail below, the dielectric layer can include one or more gaps.

As used herein, the term film and/or layer can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a structure can be or include a substrate as described herein. Structures can include features (e.g., gaps) and one or more layers overlying the features, such as one or more layers formed according to a method as described herein. A device can include or be formed using a structure.

As used herein, chemical vapor deposition (CVD) can refer to a vapor deposition process in which volatile precursors and/or reactants react and/or decompose on a surface of a substrate. During a typical CVD process, a precursor and a reactant can be flowed to a reaction chamber during an overlap period, during which both the precursor and the reactant are provided to the reaction chamber.

As used herein, the term cyclic deposition can refer to the sequential introduction of one or more precursors and/or reactants into a reaction chamber to deposit a film over a substrate and includes deposition techniques such as atomic layer deposition and cyclical chemical vapor deposition. In some cases, a cyclic deposition process can include continuously providing a reactant and/or an inert gas to a reaction chamber and pulsing a precursor to the reaction chamber. Such processes can be referred to as cyclical chemical vapor deposition or pulsed chemical vapor deposition.

As used herein, the term atomic layer deposition (ALD) may refer to a vapor deposition process in which deposition cycles, typically a plurality of consecutive deposition cycles, are conducted in a reaction chamber. Generally, during each cycle, the precursor is chemisorbed to a deposition surface (e.g., a substrate surface or a previously deposited underlying surface, such as material from a previous ALD cycle), forming a monolayer or sub-monolayer that does not readily react with additional precursor (i.e., a self-limiting reaction). Thereafter, a reactant may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. The term atomic layer deposition, as used herein, is meant to include processes designated by related terms, such as chemical vapor atomic layer deposition and the like, when performed with alternating pulses of precursor(s), reactant(s), and purge (e.g., inert carrier) gas.

As used herein, the term molybdenum precursor refers to a precursor that comprises molybdenum.

As used herein, the term molybdenum halide precursor refers to a precursor that includes molybdenum and at least one halogen. The halogen can include one or more of chlorine, iodine, and bromine.

As used herein, the term molybdenum chalcogenide halide refers to a precursor that includes a molybdenum, a halogen, and a chalcogen. The chalcogen can include one or more of oxygen (O), sulfur (S), selenium (Se), and tellurium (Te).

As used herein, the term molybdenum oxyhalide refers to a precursor that includes molybdenum, oxygen, and at least one halogen.

As used herein, the term reducing agent can refer to a reactant that donates an electron to another species in a chemical reaction.

As used herein, the term gap can refer to an opening or cavity disposed between surfaces of a non-planar structure. The term gap can refer to an opening or cavity disposed between opposing inclined sidewalls of two protrusions extending vertically from the surface of the substrate or within an indentation (e.g., having a single sidewall) extending vertically into the surface of the substrate; such gaps can be referred to as vertical gaps. The sidewall can be substantially perpendicular to a surface (e.g., bottom and/or top) or can be sloped. The term gap can also refer to an opening or cavity disposed between two opposing substantially horizontal surfaces or between two opposing substantially horizontal portions of a surface, the horizontal surfaces bounding at least a portion of the horizontal opening or cavity; such gaps may be referred to as horizontal gaps. The sidewalls between the opposing substantially horizontal surfaces or portions can be perpendicular to the surfaces or portions or can be sloped.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings.

Although a number of example materials are given throughout the embodiments of the current disclosure, it should be noted that the chemical formulas given for each of the example materials should not be construed as limiting and that the non-limiting example materials given should not be limited by a given example stoichiometry.

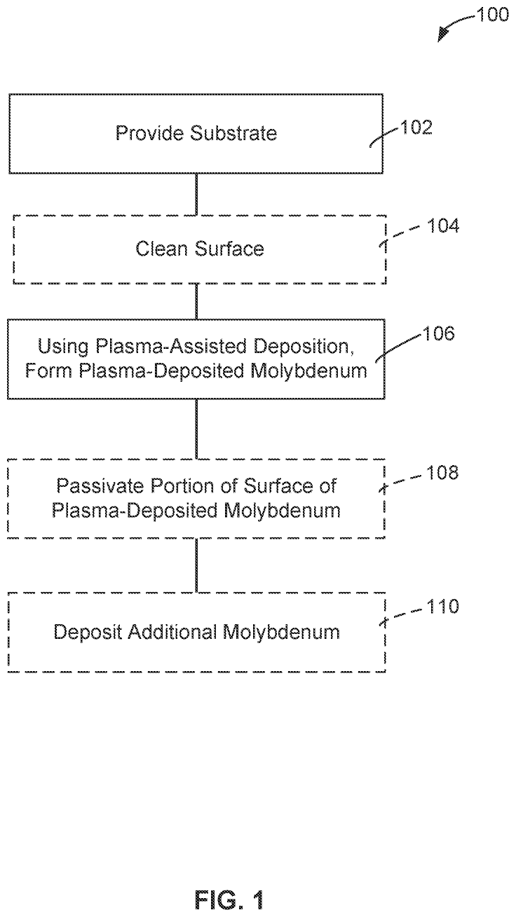

Turning now to the figures, FIG. 1 illustrates a method 100 of depositing molybdenum in accordance with exemplary embodiments of the disclosure. Method 100 includes the steps of providing a substrate (102) and using a plasma-assisted deposition process to form plasma-deposited molybdenum on a first material and on a second material (106). As illustrated, method 100 can also include one or more of: performing a surface cleaning (104), passivating a portion of a surface of the plasma-deposited molybdenum (106), and/or a step of depositing additional molybdenum (110).

During step 102, a substrate is provided within a reaction chamber. The substrate can include any substrate as described herein. By way of particular examples, the substrate can be suitable for FEOL, MOL and/or BEOL processing.

The reaction chamber used during step 102 can be or include a reaction chamber of a plasma-enhanced chemical vapor deposition reactor system configured to perform a plasma-assisted deposition process as described herein. The reaction chamber can be a standalone reaction chamber or part of a cluster tool or module.

Step 102 can include heating the substrate to a desired deposition temperature within the reaction chamber. In some embodiments of the disclosure, step 102 includes heating the substrate to a temperature of less than 350° C., less than 325° C., or less than 300° C. Additionally or alternatively, step 102 can include heating the substrate to a temperature greater than 250° C., greater than 275° C., or greater than 300° C.

In addition to controlling the temperature of the substrate, a pressure within the reaction chamber may also be regulated. For example, in some embodiments of the disclosure, the pressure within the reaction chamber during step 102 may be less than 760 torr or between about 1 torr and about 10 torr.

In accordance with examples of the disclosure, the substrate includes a surface comprising a first material and a second material. In some cases, the first material and the second material can be the same. In other cases, the second material is different than the first material. In some cases, the first material and the second material can define sections of a feature, such as a gap on the surface of the substrate.

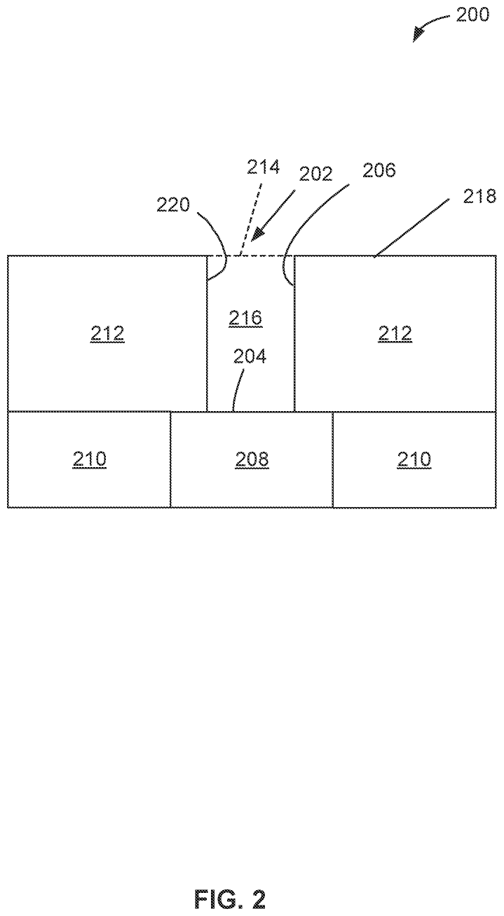

FIG. 2 illustrates a substrate 200 including a gap 202 suitable for use during step 102. In the illustrated example, gap 202 includes a first surface 204 (e.g., at a bottom of the gap) comprising the first material and a second surface 206 (e.g., on a sidewall 220 of the gap and top surface 218 of substrate 200) comprising the second material, and a volume 216. In the illustrated example, volume 216 is defined by first surface 204, second surface 206, and an imaginary line 214 across a top of gap 202.

Gap 202 is illustrated as a vertical gap. An aspect ratio (height:width) of gap 202 can be greater than 2:1, or greater than 5:1, or greater than 10:1, or greater than 25:1, or greater than 50:1, or even greater than 100:1. In some embodiments of the disclosure, the substrate may comprise one or more substantially horizontal gaps, wherein the horizontal gap may have an aspect ratio (height:width) which may be greater than 2:1, or greater than 5:1, or greater than 10:1, or greater than 25:1, or greater than 50:1. In some cases, the aspect ratio is less than 200:1, less than 150:1, less than 100:1 or less than 50:1.

In the example illustrated in FIG. 2, substrate 200 includes a first insulating material 210 and a second insulating material 212. First insulating material 210 and second insulating material 212 can be the same or different. In accordance with examples of the disclosure, first insulating material 210 and/or second insulating material 212 can be or include a dielectric material, such as an oxide or a nitride, such as silicon oxide or silicon nitride, or low-k dielectric material, such as a metal oxide. In some embodiments, first insulating material 210 and/or second insulating material 212 can be or include one or more of silicon dioxide (SiO₂), non-stoichiometric silicon oxide, silicon nitride (Si₃N₄), non-stoichiometric silicon nitride, silicon oxynitride (SiON), silicon oxycarbide (SiOC), silicon oxycarbide nitride (SiOCN), silicon carbon nitride (SiCN), or the like. In some embodiments, first insulating material 210 and/or second insulating material 212 can be or include a low dielectric constant dielectric material, such as one or more of aluminum oxide (Al₂O₃), hafnium oxide (HfO₂), tantalum oxide (Ta₂O₅), zirconium oxide (ZrO₂), titanium oxide (TiO₂), hafnium silicate (HfSiOₓ), lanthanum oxide (La₂O₃), or the like.

As illustrated, second surface 206 can be a surface of the second insulating material 212. Further, second surface 206 can extend to a top surface 218 of insulating material 212 and/or of substrate 200. In other words, the second material can be or include the second insulating material 212.

Substrate 200 also includes a material 208 at a bottom of gap 202. Material 208 can be or include, for example, conductive material. The conductive material can be or include, for example, a metal, such as tungsten, molybdenum, or the like, and/or a metal nitride, such as tungsten nitride, titanium nitride, or the like. Surface 204 can be or include the same material as material 208. In other words, the first material can be or include a conductive material.

Referring again to FIG. 1, step 106 includes using a plasma-assisted deposition process to form plasma-deposited molybdenum on the first material (e.g., surface 204) and on the second material (e.g., surface 206). In accordance with examples of the disclosure, the deposition is non-selective and/or conformal, such that molybdenum is deposited relatively evenly overlying and in contact with the first material and the second material. A selectivity of a process can be expressed as a ratio of material deposited (e.g., a layer thickness) on the first surface relative to the amount of material (e.g., a layer thickness) formed on the first and second surfaces combined. For example, if 10 nm of molybdenum is deposited on first surface 204 and 10 nm of molybdenum is deposited on second surface 206/218, the selective deposition process will be considered to be non-selective with a 50% selectivity. In accordance with examples of the disclosure, a selectivity of the plasma-deposited molybdenum on the first material relative to the second material is between about 40 percent and about 60 percent or between about 45 percent and about 55 percent. Additionally or alternatively, the plasma-deposited molybdenum can be greater than 70%, greater than 80%, greater than 90%, or greater than 95% conformal over the first and second surfaces.

A temperature and pressure within the reaction chamber during step 106 can be as described above in connection with step 102. Addition exemplary ranges for process conditions during step 102 are provided below in Table 1.

Step 106 can include providing a (e.g., first) molybdenum precursor and a (e.g., first) reactant (e.g., a reducing agent) to the reaction chamber. In accordance with examples of the disclosure, step 106 can include a cyclical plasma-assisted deposition process. In such cases, each cycle can include a precursor pulse, a reactant pulse, and/or a plasma power pulse. In some cases, the cyclical plasma-assisted deposition process comprises flowing a reactant (reducing agent) continually to the reaction chamber during one or more cycles of the cyclical plasma-assisted deposition process. In accordance with further examples, both a plasma power and precursor(s) are pulsed to the reaction chamber during each cycle of the plasma-assisted deposition process.

Exemplary molybdenum precursors suitable for use with step 106 include molybdenum halide precursors. The molybdenum halide precursors can include one or more of a molybdenum chloride precursor, a molybdenum iodide precursor, a molybdenum bromide precursor, and the like. For example, a molybdenum halide can be or include molybdenum pentachloride (MoCl₅), or the like.

In some embodiments, the molybdenum halide precursor may comprise molybdenum chalcogenide halide precursors. Exemplary molybdenum chalcogenide halide precursors include a molybdenum oxyhalide precursor selected from the group consisting of: molybdenum oxychloride, molybdenum oxyiodide, and molybdenum oxybromide. In particular embodiments of the disclosure, the molybdenum precursor includes molybdenum (IV) dichloride dioxide (MoO₂Cl₂).

A flowrate of the molybdenum precursor to the reaction chamber can be controlled and can be greater than zero and less than 1000 sccm, or less than 500 sccm, or less than 100 sccm, or less than 10 sccm, or even less than 1 sccm. For example, the flowrate can be between about 1 and 2000 sccm, between about 5 and 1000 sccm, or between about 10 and about 500 sccm. In some embodiments of the disclosure, for example, in the case of cyclical processes, the molybdenum precursor is pulsed to the reaction chamber. In such cases, the reactant and/or an inert gas can be supplied continuously or can be pulsed. A duration of each precursor pulse can be, for example, as set forth in Table 1.

As noted above, precursors may be purged from the reaction chamber—e.g., after each pulse and/or upon completion of a deposition step. A purge can be effected either in time or in space, or both. For example, in the case of temporal purges, a purge step can be used, e.g., in the temporal sequence of providing a precursor to a reactor chamber, ceasing a flow of the precursor to the reaction chamber, providing a purge gas to the reactor chamber, and providing a reactant to the reactor chamber, wherein the substrate on which a material is deposited does not move. As noted herein, in some cases, the reactant can be used as a purge gas when the precursor is not flowing to the reaction chamber. In the case of spatial purges, a purge step can take the following form: moving a substrate from a first location to which a first precursor is (e.g., continually) supplied, through a purge gas curtain, to a second location to which a second precursor is (e.g., continually) supplied. Purging times may be, for example, from about 0.01 seconds to about 20 seconds, from about 0.05 seconds to about 20 seconds, or from about 1 second to about 20 seconds, or from about 0.5 seconds to about 10 seconds, or between about 1 second and about 7 seconds.

Exemplary (e.g., first) reactants suitable for use with step 106 include reducing agents. Exemplary reducing agents include one or more of forming gas (H₂+N₂), ammonia (NH₃), hydrazine (N₂H₄), an alkyl-hydrazine (e.g., tertiary butyl hydrazine (C₄H₁₂N₂)), molecular hydrogen (H₂), hydrogen atoms (H), (e.g., C1-C4) alcohols, (e.g., C1-C4) aldehydes, (e.g., C1-C4) carboxylic acids, (e.g., B1-B12) boranes, or an amine. By way of particular examples, the first reactant can be or include at least one of hydrogen (H₂), silane (SiH₄), disilane (Si₂H₆), trisilane (Si₃H₈), germane (GeH₄), digermane (Ge₂H₆), borane (BH₃), or diborane (B₂H₆).

A flowrate of the reactant to the reaction chamber can be greater than zero and less than 100 slm, or less than 15 slm, or less than 10 slm, or less than 5 slm, or less than 1 slm, or even less than 0.1 slm. For example, the flowrate can be between about 0.1 to 30 slm, from about 5 to 15 slm, or equal to or greater than 10 slm. In the case of cyclical deposition processes, the reactant can be pulsed—e.g., for a duration between about 0.01 seconds and about 180 seconds, between about 0.05 seconds and about 60 seconds, or between about 0.1 seconds and about 30 seconds. As noted herein, in some cases, the reactant can be continuously flowed through one or more deposition cycles.

In some cases, a purge can be employed to remove any excess reactant and/or reaction byproducts from a reaction chamber—e.g., after a reactant pulse and/or at a completion of a deposition step. The purge can be as described above.

It should be appreciated that in some embodiments of the disclosure, the order providing the precursor and the reactant can be reversed. In some cases, the steps of providing the precursor and the reactant can overlap. In some cases, step 106 can comprise plasma-assisted or plasma-enhanced chemical vapor deposition. In some embodiments, a cyclical process can include providing a precursor one or more times prior to providing the reactant one or more times. Alternatively, in some embodiments, a cyclical deposition process includes providing the reactant one or more times prior to providing the precursor one or more times.

During step 106, a plasma is formed within the reaction chamber. The plasma can be formed while providing the molybdenum precursor and/or while providing the reducing agent. An inert gas, such as argon and/or helium, can be provided during step 106 to facilitate plasma formation. A flowrate of the inert gas can be between about 500 sccm and about 5000 sccm or between about 1000 and about 3000 sccm. Exemplary plasma power and plasma power pulse intervals are provided in Table 1.

In some cases, step 106 can include a cyclical deposition and etch process, wherein a cycle of the cyclical deposition and etch process comprises the plasma-assisted deposition process and a step of etching a portion of the plasma-deposited molybdenum. In such cases, an etchant can be flowed to the reaction chamber. Exemplary etchants can include molybdenum. By way of example, the etchant can be or include a molybdenum halide, which can be diluted with a diluent, such as argon, nitrogen, or the like. The molybdenum halide can be the same or similar to the molybdenum halide used during deposition. Alternatively, a molybdenum oxyhalide can be used to deposit the molybdenum and a molybdenum halide can be used as an etchant. The etchant can be exposed to a plasma. In such cases, a plasma power can be between about 125 and about 750 W. A duration of the etch can be between about 1 and about 60 or between about 10 and about 30 seconds. A flowrate of the etchant to the reaction chamber (with or without a diluent) can be between about 500 and about 5000 sccm. With reference to FIG. 2, volume 216 can be partially or completely filled using such a deposition and etch process.

TABLE 1

| Parameter | Range 1 | Range 2 | Range 3 |
|---|---|---|---|
| Temperature (° C.) | 20-350 | 250-350 | 250-300 |
| Pressure (torr) | Less than 10 | 1-10 | 1-5 |
| Precursor pulse time | Less than 2 | 0.1-2 | 0.1-1 |
| (s) | | | |
| Plasma time (s) | 0.1-30 | 2-20 | 5-15 |
| Electrode gap (mm) | 5-20 | 9-18 | 10-14 |
| Plasma power (W) | Greater than 125 | 125-750 | 300-400 |

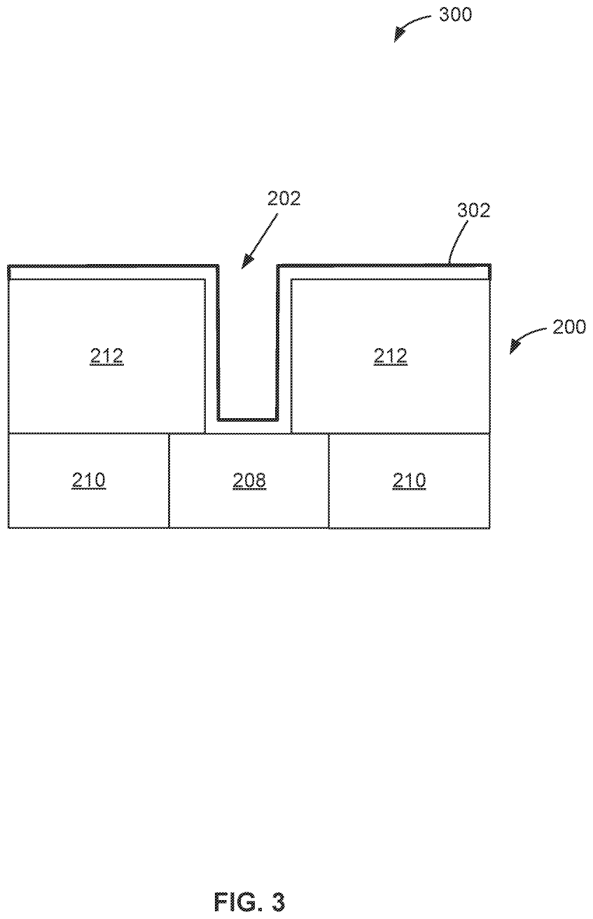

FIG. 3 illustrates a structure 300 after completion of step 106. As illustrated, Structure 300 includes substrate 200 and plasma-deposited molybdenum 302 comprising molybdenum. A thickness of plasma-deposited molybdenum 302 can be between about 1 nm and about 10 nm or between about 2 nm and about 5 nm. A selectivity of plasma-deposited molybdenum 302 overlying the first material and the second material (surface 204 and surface 206) can be as described above.

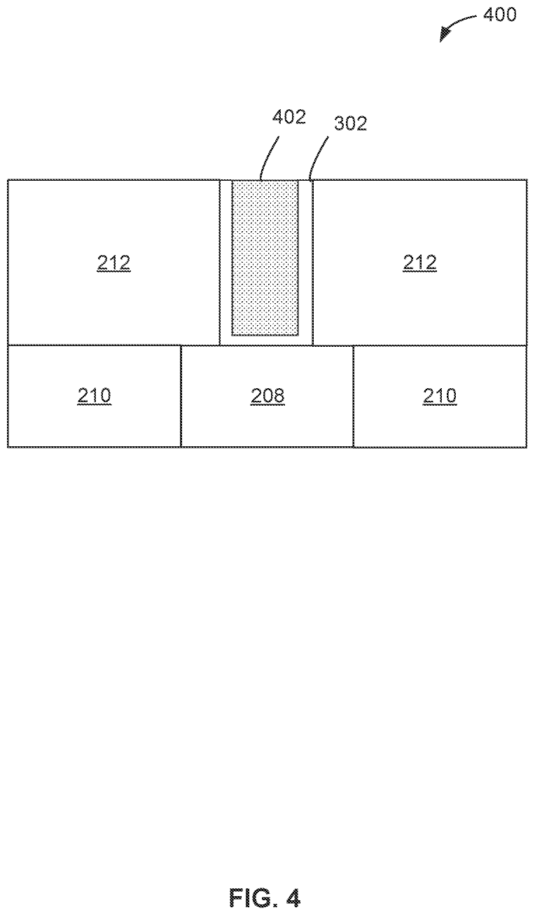

Referring now to FIGS. 1 and 4, after step 106 of using a plasma-assisted deposition process to form plasma-deposited molybdenum on the first material and on the second material, method 100 can include deposing additional molybdenum (110). The additional molybdenum can be plasma-deposited molybdenum or thermally-deposited (without formation of a plasma). In the case of plasma-assisted deposition during step 110, the parameters can be as set forth in Table 1 or in Table 2. In some cases, a pressure can be higher during step 110, compared to step 106. Additionally or alternatively, a precursor pulse time can be higher during step 110, compared to step 106. Additionally or alternatively, the reactant pulse time can be shorter during step 110, compared to step 106. Additionally or alternatively, the gap can be greater during step 110, compared to step 106. Additionally or alternatively, the plasma power can be lower during step 110, compared to step 106.

When step 110 includes thermal deposition, a temperature within a reaction chamber (e.g., another reaction chamber) can be between about 275 and about 400° C. or between about 300 and about 350° C. A pressure within the reaction chamber can be between about 20 and about 80 torr or between about 30 and about 50 torr.

Similar to step 106, step 110 can include providing a (e.g., second) molybdenum precursor to the reaction chamber and providing a (e.g., second) reactant/reducing agent to the reaction chamber. The second molybdenum precursor can be or include any molybdenum precursor noted above. For example, the first molybdenum precursor and the second molybdenum precursor can comprise the same or different molybdenum compounds. Similarly, the second reactant can be or include any of the same or different reactants noted above. Flowrates, pulse durations, reaction chamber pressures, and reaction chamber temperatures can be as noted above. And, similar to step 106, step 110 can be a cyclic process or can be a CVD process.

FIG. 4 illustrates a structure 400 including additionally-deposited molybdenum 402 overlying plasma-deposited molybdenum 302. As illustrated, additionally-deposited molybdenum 402 can be used to fill a remaining portion of volume 216. In accordance with examples of the disclosure, about 50 to about 90 percent, or about 10 to about 50 percent, or about 0 to about 50 percent of the volume is filled using step 110.

Returning again to FIG. 1, method 100 can include a step of performing a surface cleaning within the reaction chamber (104). During step 104, a reducing agent can be provided to the reaction chamber. The reducing agent can include, for example, any reducing agent described herein. The reducing agent can be exposed to a plasma to form excited species. A flowrate of the reducing agent to the reaction chamber during step 104 can be between about 1000 and about 5000 sccm. A power used to form the plasma can be between about 150 and about 500 W. A duration of step 104 can be between about 30 and about 180 seconds.

With further reference to FIG. 1, method 100 can additionally include passivating a portion of a surface of the plasma-deposited molybdenum (108). Step 108 can be prior to the step of step 110.

During step 108, a passivating agent is provided to the reaction chamber or to another reaction chamber. The passivating agent can be used to inhibit deposition on a portion of the substrate, such as a top portion of gap 202. In some cases, the passivating agent is an organic passivating agent. Particular exemplary passivating agents suitable for step 108 include one or more of trimethylsilyl dimethylamine, acetylacetone, fluorocarbon, octadecylphosphonic acid.

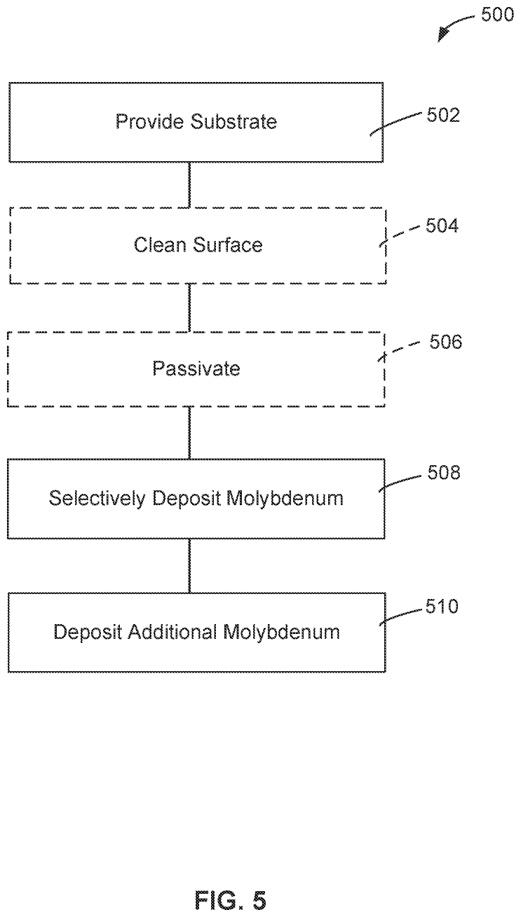

Turning now to FIG. 5, another method 500 in accordance with examples of the disclosure is illustrated. Method 500 includes the steps of providing a substrate within a reaction chamber (502), selectively depositing the molybdenum to form selectively-deposited molybdenum (508) and depositing additional molybdenum (510). Method 500 can also include a step of cleaning a surface (504) and/or passivating a portion of the surface (506). Method 500 is similar to method 100, except method 500 includes a selectively depositing molybdenum step (508) followed by depositing additional molybdenum (510).

Steps 502 and 504 of method 500 can be the same or similar to steps 102, 104 of method 100. Step 506 can be similar to step 108, except step 506 is performed on a substrate surface or a cleaned substrate surface.

During step 508, molybdenum is selectively deposited onto on the first material relative to the second material. The selectivity can be greater than 60 percent, greater than 70 percent, greater than 80 percent, or greater than 90 percent.

Step 508 can be a plasma-assisted process or a thermal process. In the case of a thermal process, step 508 can be the same or similar to the thermal process described above in connection with step 110.

In the case of plasma-assisted processes, the conditions during step 508 can be tuned to promote selective deposition. The conditions can be similar to the conditions described above in connection with step 106. Exemplary conditions are set forth in Table 2.

TABLE 2

| Parameter | Range 1 | Range 2 | Range 3 |
|---|---|---|---|
| Temperature (° C.) | 20-350 | 250-350 | 250-300 |
| Pressure (torr) | Less than 10 | 1-10 | 7-10 |
| Precursor pulse time | Less than 2 | 0.1-2 | 1-1.5 |
| (s) | | | |
| Plasma time (s) | 0.1-30 | 0.5-5 | 2-5 |
| Electrode gap (mm) | 5-20 | 9-18 | 14-18 |
| Plasma power (W) | Greater than 125 | 125-750 | 125-200 |

In some cases, a pressure can be higher during step 508, compared to step 106. Additionally or alternatively, a precursor pulse time can be higher during step 508, compared to step 106. Additionally or alternatively, the reactant pulse time can be shorter during step 508, compared to step 106. Additionally or alternatively, the gap can be greater during step 508, compared to step 106. Additionally or alternatively, the plasma power can be lower during step 508, compared to step 106. Step 508 can include a deposition and etch process as described above, with the deposition process tuned for selective deposition.

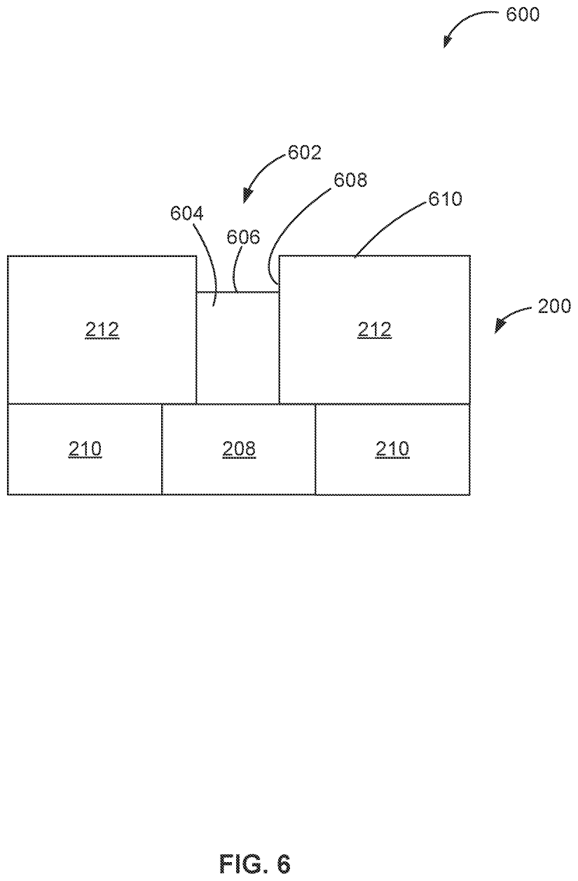

FIG. 6 illustrates a structure 600 after step 508. In the illustrated example, substrate 200 and components thereof can be as described above. Selectively-deposited (e.g., thermally or plasma-assisted) molybdenum 606 can be formed within a gap 602 on a surface of the substrate. Molybdenum 606 can be selectively formed overlying and in contact with first/conductive material 208, compared to second/dielectric material 212.

Once a desired amount of molybdenum is selectively deposited within gap 602 (e.g., about 10-90 vol. percent or about 20-80 vol. percent, or about 30-70 vol. percent), additional molybdenum is deposited onto a surface of the substrate during step 510.

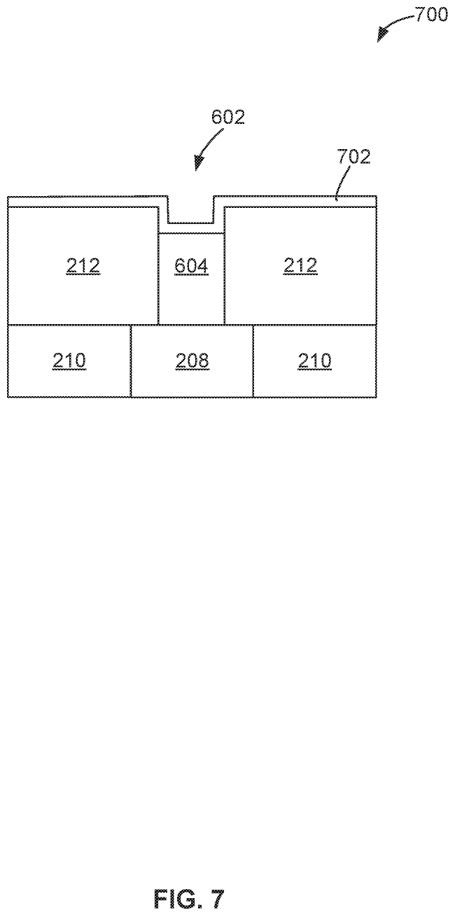

FIG. 7 illustrates a structure 700, including additional molybdenum 702 deposited over selectively-deposited molybdenum 604. As illustrated, additional molybdenum 702 can be deposited non-selectively overlying surface 606 of selectively-deposited molybdenum 604 and overlying surface 610 of dielectric/second material 212. As above, the non-selective deposition can have a selectivity of between about 40% and about 60%.

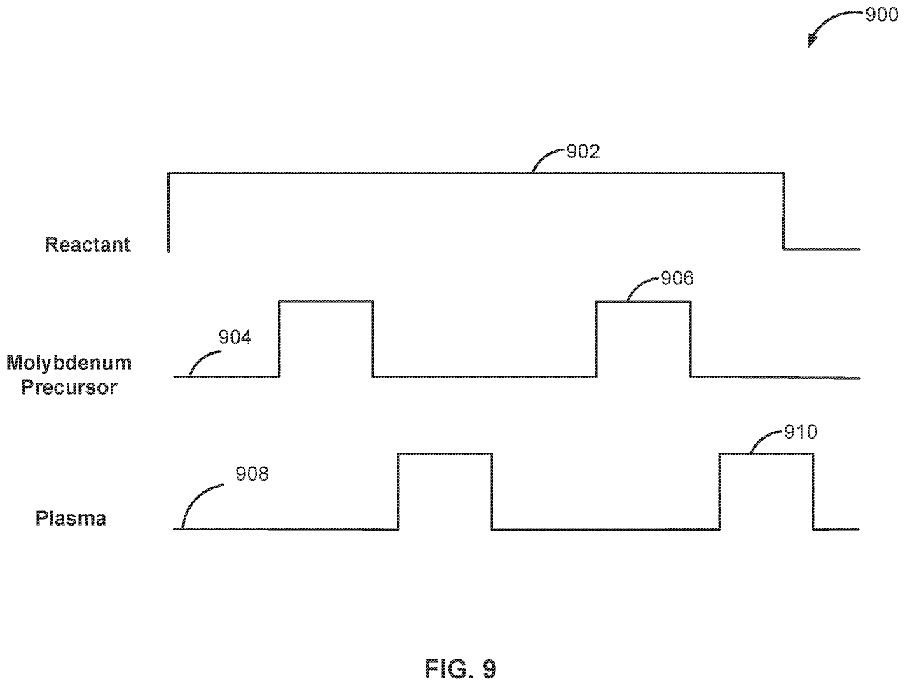

FIG. 9 illustrates an exemplary timing sequence 900 suitable for use with examples of method 100 and/or method 500 (e.g., steps 106, 110, 508 and/or 510). Sequence 900 illustrates a pulsed or cyclical plasma-assisted CVD process.

Timing sequence 900 includes a reactant duration line 902 and a molybdenum precursor pulse line 904, including molybdenum precursor pulses 906, and a plasma power duration line 908, including plasma power pulses 910. Each cycle of timing sequence 900 can include a molybdenum precursor pulse 906 and a plasma power pulse 910. As illustrated, timing sequence 900 can include continuously providing a reactant during one or more deposition cycles, while pulsing the molybdenum precursor and/or plasma power. Alternatively, the reactant can be pulsed before, after, and/or during molybdenum precursor pulse 906.

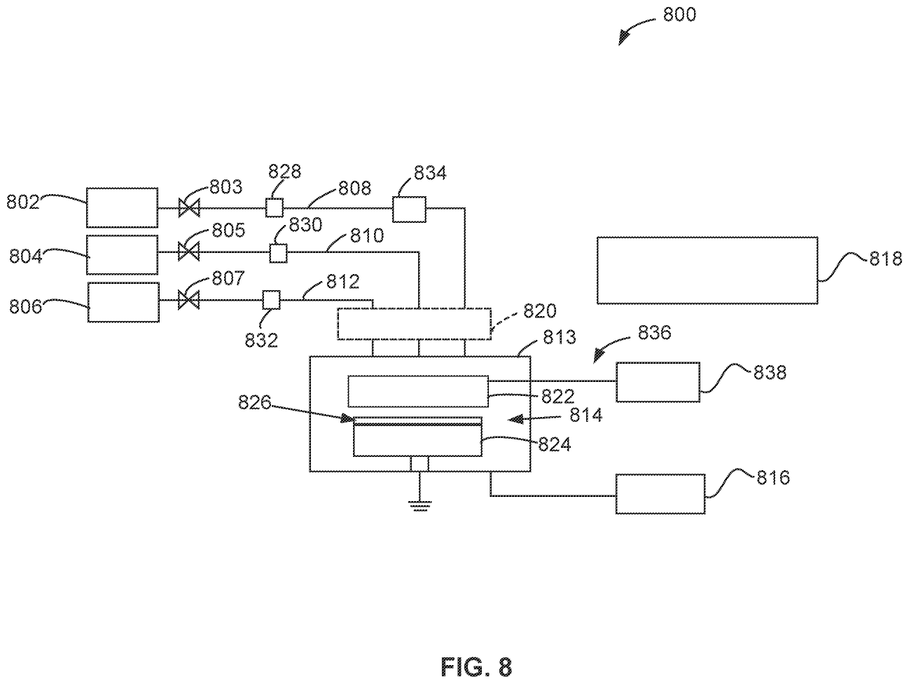

Turning now to FIG. 8, a system 800 in accordance with exemplary embodiments of the disclosure is illustrated. System 800 can be used to perform a method as described herein and/or various method steps as described herein.

In the illustrated example, system 800 includes one or more reactors 813—each including one or more reaction chambers 814—a precursor source 802 in fluid communication via a first flow control valve 803 and line 808 with the one or more reaction chambers 814, a reactant source 804 in fluid communication via a second flow control valve 805 and line 810 with the one or more reaction chambers 814, a purge source 806 in fluid communication via a third flow control valve 807 and line 812 with the one or more reaction chambers 814, an exhaust source 816, and a controller 818. The system 800 can optionally include a remote plasma source 820 and/or a direct apparatus 836, including a plasma power source 838 to excite a gas (e.g., during a cleaning or deposition step) from one or more sources 802-806 or another gas source. Further, as illustrated, system 800 can include one or more pressure flow controllers or mass flow controllers 828-832 associated with lines 808-812, respectively. Additionally, to facilitate rapid, relatively large doses of the molybdenum precursor, system 800 can include an accumulator 834 in fluid communication between precursor source 802 and reaction chamber 814. Accumulator 834 can allow for higher precursor dose delivery, compared to conventional reactor systems.

Reaction chamber 814 can include any suitable reaction chamber, such as a plasma-enhanced atomic layer deposition (ALD) or chemical vapor deposition (CVD) reaction chamber. The reaction chamber 814 can include a gas distribution system 822, such as a showerhead (which can form part of a direct or indirect plasma electrode), and a susceptor 824 to retain a substrate 826.

Exhaust source 816 can include one or more vacuum pumps to remove gas from the reaction chamber 814. Substrate 826 can be any substrate or structure described herein.

Precursor source 802 can include a vessel and a molybdenum precursor, such as one or more molybdenum precursors described herein.

Reactant source 804 can include a vessel and a reactant. The reactant can be or include a reducing agent as described herein.

Purge source 806 can include a vessel and one or more purge gases. For example, purge source 806 can include one or more of nitrogen, argon, or the like.

Controller 818 can include electronic circuitry and software to selectively operate flow control valves 803-807, manifolds, heaters, pumps, and other components included in system 800. Such circuitry and components can operate to introduce precursors, reactants, and purge gases from the respective sources 802-806. Controller 818 can control timing of gas pulse sequences, temperature of the substrate and/or reaction chamber, pressure within the one or more reaction chambers 814, and various other operations to provide proper operation of system 800. Controller 818 can include software to electrically or pneumatically operate flow control valves to provide the precursors from precursor source 802 and the reactant from reactant source 804 into one or more reaction chambers 814. Controller 818 can also include software to provide purge gases into and out of the one or more reaction chambers 814.

Controller 818 can include modules, such as a software or hardware component, e.g., a FPGA or ASIC, which perform certain tasks. A module can advantageously be configured to reside on the addressable storage medium of the control system and be configured to execute one or more processes.

By way of examples, controller 818 can be configured to operate flow control valves and heaters to: non-selectively or conformally deposit plasma-deposited molybdenum on a first surface (e.g., at a bottom of a gap) on a substrate relative to a second surface (e.g., on a sidewall of the gap) to at least partially fill the gap and thereafter deposit additional molybdenum over the first surface and a second surface. Alternatively, controller 818 can be configured to selectively deposit molybdenum and thereafter use a plasma-assisted process to non-selectively or conformally deposit molybdenum on the selectively-deposited molybdenum.

Other configurations of system 800 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the one or more reaction chambers 814. Further, as a schematic representation of an apparatus, many components have been omitted for simplicity of illustration; such components may include, for example, various valves, manifolds, purifiers, heaters, containers, vents, and/or bypasses.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of depositing molybdenum, the method comprising the steps of:
providing a substrate within a reaction chamber, the substrate comprising a surface comprising a first material and a second material different than the first material; and
using a plasma-assisted deposition process to form plasma-deposited molybdenum on the first material and on the second material,
wherein a temperature within the reaction chamber during the step of using the plasma-assisted deposition process is less than 350° C.; and
wherein a selectivity of the plasma-deposited molybdenum on the first material relative to the second material is between about 40 percent and about 60 percent.

2. The method of claim 1, wherein the second material comprises a dielectric material.

3. The method of claim 1, wherein the first material comprises a conductive material.

4. The method of claim 1, wherein the substrate comprises a feature having a bottom surface comprising the first material and a side surface comprising the second material.

5. The method of claim 4, wherein the feature comprises a gap.

6. The method of claim 1, comprising a cyclical deposition and etch process, wherein a cycle of the cyclical deposition and etch process comprises:
the plasma-assisted deposition process; and
a step of etching a portion of the plasma-deposited molybdenum.

7. The method of claim 6, wherein the step of etching comprises using an etchant comprising molybdenum.

8. The method of claim 7, wherein the step of etching comprises using an etchant comprising a molybdenum halide.

9. The method of claim 8, comprising filling the gap using the cyclical deposition and etch process.

10. The method of claim 1, wherein the temperature within the reaction chamber during the step of using the plasma-assisted deposition process is greater than 250° C.

11. The method of claim 1, wherein a plasma power during the step of using the plasma-assisted deposition process is greater than 125 W.

12. The method of claim 1, wherein a plasma power during the step of using the plasma-assisted deposition process is between 125 W and 750 W.

13. The method of claim 1, further comprising a step of forming thermally-deposited molybdenum overlying the plasma-deposited molybdenum.

14. The method of claim 13, further comprising a step of passivating a portion of a surface of the plasma-deposited molybdenum prior to the step of forming thermally-deposited molybdenum.

15. The method of claim 14, wherein the step of passivating comprises providing an organic passivating agent.

16. The method of claim 15, wherein the organic passivating agent comprises one or more of trimethylsilyl dimethylamine, acetylacetone, fluorocarbon, octadecylphosphonic acid.

17. The method of claim 1, further comprising a step of performing a surface cleaning within the reaction chamber.

18. The method of claim 1, wherein a plasma-assisted deposition process comprises a cyclical plasma-assisted deposition process, wherein a reducing agent is continually flowed to the reaction chamber during one or more cycles of the cyclical plasma-assisted deposition process.

19. A method of depositing molybdenum, the method comprising the steps of:
providing a substrate within a reaction chamber, the substrate comprising a surface comprising a first material and a second material;
conformally depositing the molybdenum to form-deposited molybdenum on the first material and the second material,
wherein the deposited molybdenum is greater than 70% conformal on the first material and on the second material, and
wherein a temperature within the reaction chamber during the step of conformally depositing is less than 350° C.

20. A method of depositing molybdenum, the method comprising the steps of:
providing a substrate within a reaction chamber, the substrate comprising a surface comprising a first material and a second material different than the first material;
using a cyclical plasma-assisted deposition process to form plasma-deposited molybdenum on the first material and the second material, wherein a temperature within the reaction chamber during the step of using the plasma-assisted deposition process is less than 350° C., and wherein a selectivity of the plasma-deposited molybdenum on the first material and on the second material is between about 40 percent and about 60 percent; and
thermally depositing thermally-deposited molybdenum overlying the plasma-deposited molybdenum.
